(19) United States
(12) Patent Application Publication
(10) Pub. No.: US 2013/0213474 A1
(43) Pub. Date: Aug. 22, 2013

(54) Method and device for increasing solar cell output

(71) Applicant: Brent Ellis Logan, Mount Vernon, WA (US)

(72) Inventor: Brent Ellis Logan, Mount Vernon, WA (US)

(21) Appl. No.: 13/694,605

(22) Filed: Dec. 17, 2012

Related U.S. Application Data
(60) Provisional application No. 61/630,702, filed on Dec. 19, 2011.

(51) Int. Cl. H01L 31/052

(52) U.S. Cl. CPC H01L 31/0524; H01L 31/0525
USPC 136/259

(57) ABSTRACT

To optimize photovoltaic energy in situ and without expensive heliostat systems, the power from full, diffracted, as well as low-angle sunlight can be significantly increased by utilizing flat or curved reflectors and/or lenses in any configuration around and/or above a solar cell, attached or independent, no matter the size or how situated, alone or multiply, with supports, heat sinks, or cooling vanes enclosed partly or entirely in a protective transparent envelope; enhanced photonic capture by this integrally reflective and modular CSP technology could with increased cell receptivity be further employed for nocturnal usage from stellar, lunar, and urban illumination as well as office, store, and household lighting both night and day.

### CROSS-REFERENCE TO RELATED APPLICATIONS

This application claims the benefit of U.S. Provisional Patent Application No. 61/630,702 having a file date of Dec. 19, 2011, the primary contents of which are herewith incorporated by reference.

### REFERENCES CITED

U.S. Patent Documents

| | | |
|---|---|---|
| 20060201498 | Sep. 14, 2006 | Olsson |
| 20090084375 | Apr. 2, 2009 | Xie |
| 7,952,057 | May 31, 2011 | Finot, et al. |
| 8,030,605 | Oct. 4, 2011 | Grassmann |
| 8,039,732 | Oct. 18, 2011 | Arkas, et al. |
| 8,063,300 | Nov. 22, 2011 | Horne, et al. |

### STATEMENT REGARDING FEDERALLY SPONSORED RESEARCH OR DEVELOPMENT

Not Applicable

### REFERENCE TO SEQUENCE LISTING, A TABLE, OR A COMPUTER PROGRAM LISTING COMPACT DISK APPENDIX

Not Applicable

### BACKGROUND OF THE INVENTION

According to the photoelectric effect, solar cells produce electrical energy that is proportionate to the amount of light energy falling upon them. By increasing the amount of light on a solar panel with adequate capacitance, it is possible to generate an equivalent multiple of electricity.

To maximize sunlight reaching photovoltaic cells, solar tracking systems orient flat panels at or near right angles to the sun's rays—but this technology is costly and subject to mechanical as well as power breakdowns. Yet even when the sun is only ten degrees above the horizon its available energy can already be half or greater—depending upon latitude, season, and atmospheric conditions—the level at noon. If stationary solar cells received greater light energy without requiring expensive improvements, in addition to new usage the net operational cost could justify replacement of existing technology—whether fixed horizontal or vertical (two- and three-dimensional) systems; such power enhancement would nonetheless apply to technology utilizing altazimuth orientation.

### BRIEF SUMMARY OF THE INVENTION

Considered as a Concentrated Solar Power (CSP) device, reflecting panels of material with a suitably mirrored surface can be positioned along both latitudinal sides of a rectangular photovoltaic cell (orienting to the sun's diurnal east-west motion) and at the longitudinal ends (for seasonal changes in the sun's path) to redirect rays adjacently outside its edges upon the cell, obeying the Law of Reflection for flat mirrors—where the angle of reflection equals the incidental angle; omitting reflectors from either of the two axes would still convey more light to a cell's surface than their absence. A second tier of reflectors could extend daily photonic input to the cell through angular capture of light at different times, with additional fixed tiers if advantageous, thereby meeting or exceeding the performance of costly heliostat systems, although these could as well benefit from this CSP device. Adjunct panel sizes and reflecting angles can vary, as long as their conveyance of light results in a total daily illumination increase over the sun's rays alone falling directly on the cell's surface, therefore this device in single or multiple tiers could be positioned around a solar cell of any shape—triangular, hexagonal, circular, or freeform.

Based upon the power requirement, a rectangular reflector can abut—or be joined at its periphery to—like panels, thus forming a tesselated grid of any size, with triangular and hexagonal reflectors also appropriate for this purpose. Significant temperature elevation of materials would be addressed through standard heat sinks or with external cooling vanes also serving as reflector supports. A transparent cover attached to the reflectors' perimeter could protect their surfaces, as well as that of the photovoltaic cell by complete or partial enclosure, thus constituting a modular unit, and provide ease of cleaning for maximal light transmission; miniature reflector lattice or waffle grids could be embedded entirely or partly in a transparent material, thus constituting a CSP variant of multiple usages for field optimization.

Such light enhancement could be furthered by one or more reflecting panels located directly over and facing a solar cell of any shape, positioned parallel or at an angle to it, attached to the periphery of the other reflectors, or affixed to the transparent cover's underside, sufficiently sized for returning the adjacent reflectors' rays to the cell's surface yet not reducing direct sunlight beyond its net optimization of this system. The parallel reflector might be concave to intensify energy at the cell's surface provided the resulting temperature would not substantially decrease efficiency even with traditional heat sinks or external cooling vanes, however, a convex reflector could direct light more broadly, thereby conveying additional energy to the cell and adjacent reflectors without producing an excessive increase in temperature. Strategically placed convex or concave lenses can also amplify cellular photonic access. Including those structured as cooling vanes, supports for the one or more tiered or overhead reflecting panels can be made of various sturdy materials including protective transparent walls that permit a partial or completely enclosed assembly, the surfaces of which are easily cleaned for optimal light transmission.

Improvement over the present CSP art is based upon angled reflectors directing more photons onto a planar solar cell surface for amplified intensity and longer duration, thereby creating a richer photonic field, essentially a hive of light which can serve as a constantly renewable power resource. Greater energy from early morning and late afternoon low-angle incident light is captured, with other times addressed by additional reflector tiers at different angles, thus providing a cumulative net increase of daily power production per cell; as confirmed from extensive testing by the inventor this novel enhancement in photovoltaic technology functions especially well where ambient light is uniformly diffracted by clouds, fog, haze, or smog. Improvements in cell receptivity to low light would enable the innovation—perhaps benefitting from concave or convex reflectors and lenses—to be utilized nocturnally, where stellar and lunar illumination could become an energy resource, as well as any vertical or other three-dimensional embodiment of the invention for tapping urban building light; this same principle can apply to indoor usage in offices, stores, or homes. The overall effect of this device in each of its iterations is to convey more light from singular and/or multiple reflection to a photovoltaic cell depending upon reflector angulature, the latter configuration creating a photonic reverberance among reflectors until striking the cell surface.

The present invention and its relevant applications do not exhaust the spectrum of definitive variants. A search of U.S. patents issued and applied for, along with technical literature, discloses no prior art specific to this innovation's scope or features.

### BRIEF DESCRIPTION OF THE DRAWINGS

The unique features that are characteristic of the present invention are set forth in the claims below. However, the preferred embodiments of this invention, together with further objects and attendant advantages, are best understood by reference to the following detailed description taken in connection with the accompanying drawings in which:

FIG. 1 is side perspective of the device with single-tier reflectors, showing structural supports and a protective cover comprised of an underside reflector and a surrounding lense or lenses.

FIG. 2 is a side perspective of the device with double-tier reflectors, showing structural supports and a protective cover.

FIG. 3 is top perspective of the device in a multicell array with single-tier reflectors.

### DETAILED DESCRIPTION OF THE INVENTION

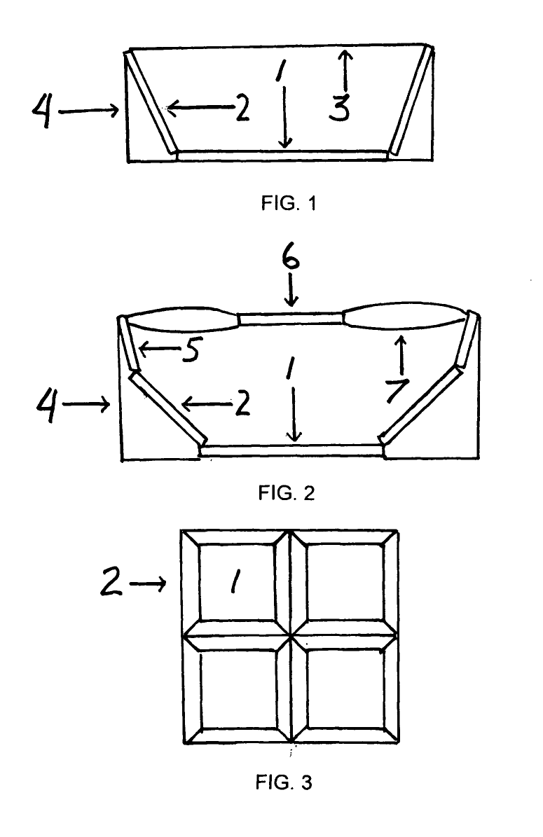

Referring to FIG. 1, one embodiment of the present innovation in a side perspective illustrates a photovoltaic cell, 1, surrounded by a single tier of reflectors, 2, protected by a transparent cover, 3, and supported in a frame, 4, which may also consist of cooling vanes.

Referring to FIG. 2, another embodiment of the present innovation in a side perspective depicts a photovoltaic cell, 1, surrounded by a double tier of reflectors, 2 and 5, at different angles in relation to each other and the solar cell, supported in a frame, 4, with an overhead reflector, 6, and surrounding lens or lenses, 7, these also constituting a protective cover, 6.

Referring to FIG. 3, one embodiment of the present innovation viewed from an overhead perspective shows photovoltaic cells, 1, surrounded by a single tier of reflectors, 2, in a tessellated grid.

I claim:

1. A Concentrated Solar Power (CSP) device comprised of flat reflective panels attached or independently positioned along the latitudinal sides of a rectangular photovoltaic cell or cell combination (thereby orienting to the sun's diurnal east-west motion) or at the longitudinal ends (thus orienting to seasonal changes in the sun's path), or both, to redirect by appropriate angulature rays falling adjacently outside its periphery upon the cell or cell combination, said cell or cells and device being fixed, tiltable, or heliostatic, hence extending daily input to the cell or cells at different times along with amplifying the cell's or cells' net daily power output.

2. The CSP device of claim 1, wherein multiple tiers of flat reflectors are added.

3. The CSP device of claim 1, wherein its reflectors are positioned around a solar cell or cell combination of any shape, whether triangular, hexagonal, circular, or freeform.

4. The CSP device of claim 2, wherein its tiered reflectors are positioned around a solar cell or cell combination of any shape, whether triangular, hexagonal, circular, or freeform.

5. The CSP device of claim 1, wherein concave or convex reflectors are utilized exclusively or in combination with flat reflectors.

6. The CSP device of claim 2, wherein tiered concave or convex reflectors are utilized exclusively or in combination with flat reflectors.

7. The CSP device of claim 3, wherein tiered concave or convex reflectors are utilized exclusively or in combination with flat reflectors.

8. The CSP device of claim 1, wherein flat, concave, or convex reflectors are exclusively or in combination with peripheral reflectors positioned directly overhead, parallel to or angled toward a solar cell or cell combination.

9. The CSP device of claim 2, wherein flat, concave, or convex reflectors are exclusively or in combination with tiered peripheral reflectors positioned directly overhead, parallel to or angled toward a solar cell or cell combination.

10. The CSP device of claim 3, wherein flat, concave, or convex reflectors are exclusively or in combination with peripheral reflectors positioned directly overhead, parallel to or angled toward a solar cell or cell combination.

11. The CSP device of claim 4, wherein flat, concave, or convex reflectors are exclusively or in combination with peripheral reflectors positioned directly overhead, parallel to or angled toward a solar cell or cell combination.

12. The CSP device of claim 5, wherein flat, concave, or convex reflectors are exclusively or in combination with peripheral reflectors positioned directly overhead, parallel to or angled toward a solar cell or cell combination.

13. The CSP device of claim 6, wherein flat, concave, or convex reflectors are exclusively or in combination with peripheral reflectors positioned directly overhead, parallel to or angled toward a solar cell or cell combination.

14. The CSP device of claim 7, wherein flat, concave, or convex reflectors are exclusively or in combination with peripheral reflectors positioned directly overhead, parallel to or angled toward a solar cell or cell combination.

15. The CSP device of claim 1, wherein concave or convex lenses are utilized to amplify photonic access by a solar cell or cells.

16. The CSP device of claim 2, wherein concave or convex lenses are utilized to amplify photonic access by a solar cell or cells.

17. The CSP device of claim 3, wherein concave or convex lenses are utilized to amplify photonic access by a solar cell or cells.

18. The CSP device of claim 4, wherein concave or convex lenses are utilized to amplify photonic access by a solar cell or cells.

19. The CSP device of claim 5, wherein concave or convex lenses are utilized to amplify photonic access by a solar cell or cells.

20. The CSP device of claim 6, wherein concave or convex lenses are utilized to amplify photonic access by a solar cell or cells.

21. The CSP device claim 1 and all subsequent claim iterations, wherein a protective transparent cover is attached to the reflectors' periphery or completely encloses both reflectors and a solar cell or cells.
